(19) United States
(12) Patent Application Publication
(10) Pub. No.: US 2016/0276545 A1
(43) Pub. Date: Sep. 22, 2016

(54) ELECTRONIC COMPONENT AND METHOD FOR PRODUCING AN ELECTRONIC COMPONENT

(71) Applicant: OSRAM OPTO SEMICONDUCTORS GMBH, Regensburg (DE)

(72) Inventors: Johannes Mueller, Tittmoning (DE); Christoph Koller, Hemau (DE); Thomas Schwarz, Regensburg (DE); Frank Singer, Regenstauf (DE)

(21) Appl. No.: 15/033,157

(22) PCT Filed: Oct. 16, 2014
(86) PCT No.: PCT/EP2014/072180

§ 371 Date: Apr. 29, 2016

(30) Foreign Application Priority Data
Oct. 31, 2013 (DE) 10 2013 222 200.9

(51) Int. Cl. H01L 33/48; H01L 33/00; H01L 33/60; H01L 33/54; H01L 33/62

(52) U.S. Cl. CPC H01L 33/486; H01L 33/54; H01L 33/62; H01L 33/60; H01L 33/005; H01L 2933/005; H01L 2933/0066; H01L 2933/0033

(57) ABSTRACT

In various embodiments, a method for producing an electronic component is provided. The method includes applying an adhesive layer to a carrier, initially curing the adhesive layer applied to the carrier, providing a chip, wherein the chip has a substrate and a layer sequence arranged on the substrate, laying the chip onto the initially cured adhesive layer by way of a top side of the layer sequence, embedding the chip into a shaped body, wherein the top side of the layer sequence and a first side of the shaped body lie substantially in a plane, separating the embedded chip from the adhesive layer and the carrier, and applying an electrically conductive structure to the first side of the shaped body, the shaped body forming a vertical electrical insulation between the electrically conductive structure and the substrate.

### RELATED APPLICATIONS

The present application is a national stage entry according to 35 U.S.C. §371 of PCT application No.: PCT/EP2014/072180 filed on Oct. 16, 2014, which claims priority from German application No.: 10 2013 222 200.9 filed on Oct. 31, 2013, and is incorporated herein by reference in its entirety.

### TECHNICAL FIELD

Various embodiments relate to an electronic component in which a chip is embedded in a shaped body, and to a method for producing a corresponding electronic component.

### BACKGROUND

In the case of electronic components, for example in the case of semiconductor components, it is known to arrange semiconductor chips on carrier substrates. The carrier substrate may be, for example, a silicon or ceramic substrate, a conductor track strip (lead frame) or what is termed a metal core board. The carrier substrate may be provided as a mechanical carrier, for electrical contact connection, for wiring to further components, for example protective diodes, for heat spreading and/or for heat dissipation. In the case of some components, such as for example optoelectronic components, the carrier substrate can moreover be provided as a carrier for an optical lens. Conventional carrier substrates are relatively costly, however. As a result of a requisite minimum size of the carrier substrates, these are responsible for a significant proportion of the total production costs.

Molding compound is therefore increasingly being used in the production of electronic components in order to mold mechanical carriers for the chips. The document DE 10 2009 036 621 A1, for example, discloses an optoelectronic semiconductor component, in which a shaped body covering the side faces of the chip is formed from molding compound, with merely one side face of the chip remaining free or being exposed.

A light-emitting region and also one or more connection contacts may be provided on the exposed side face of the embedded chip. In addition, electrically conductive structures may be arranged on or in the shaped body. In order to prevent undesired electrically conductive connections between the connection contacts, the electrically conductive structures and the substrate, insulation structures can be formed, for example, by the application of an insulating material. The application of the insulating material involves a plurality of sub-steps, however, and therefore the application of the insulating material is relatively time-consuming and costly.

It is therefore an object to provide a method for producing an electronic component, in particular for producing insulation structures. It is a further object to provide a corresponding electronic component.

### SUMMARY

To achieve the object, what is proposed is a method in which an adhesive layer is applied to a carrier. The adhesive layer applied to the carrier is initially cured. Provision is made of a chip. The chip has a substrate and a layer sequence arranged on the substrate. The chip is laid onto the initially cured adhesive layer by way of a first top side of the layer sequence. The chip lying on the adhesive layer is embedded into a shaped body, the top side of the layer sequence and a first side of the shaped body lying substantially in a plane. The chip embedded in the shaped body is separated from the adhesive layer and the carrier. An electrically conductive structure is applied to the first side of the shaped body, the shaped body forming a vertical electrical insulation between the electrically conductive structure and the substrate.

By virtue of the initial curing of the adhesive layer, the viscosity and/or the tackiness of the adhesive layer can be set in such a way that the chip does not sink or sinks only to a very small extent into the adhesive layer when it is laid onto the adhesive layer. Furthermore, the viscosity and/or the tackiness of the adhesive layer can be set in such a way that the adhesive layer does not wet the edge of the layer sequence and/or the edge of the chip. By virtue of the initial curing of the adhesive layer, it is possible to form a shaped body of which the first side lies substantially in a plane with the top side of the layer sequence. The shaped body, in particular that region of the shaped body which forms the vertical electrical insulation, can laterally surround the layer sequence. Furthermore, that region of the shaped body which forms the vertical electrical insulation can cover a marginal region of the substrate. A separate electrical insulation of the substrate or of the marginal region of the substrate is therefore not required. Since the vertical insulation is formed as part of the shaped body, the number of method steps can be reduced.

During the formation of the shaped body, i.e. during the embedding of the chip, the chip lies on the adhesive layer by way of the top side of the layer sequence. As a result, the top side of the layer sequence can be shielded from the molding compound. The top side of the layer sequence is therefore generally free from molding compound after separation from the carrier. It is therefore possible to dispense with subsequent cleaning of the top side of the layer sequence.

To achieve the object, what is furthermore proposed is an electronic component. The electronic component includes a chip embedded into a shaped body, wherein the chip includes a substrate and a layer sequence arranged on a first side of the substrate. The shaped body has a first side. The first side of the shaped body and a top side of the layer sequence lie substantially in a plane. The top side of the layer sequence is free from molding compound. An electrically conductive structure is arranged on the first side of the shaped body. A region of the shaped body forms a vertical electrical insulation between the electrically conductive structure and the substrate.

The term “initial curing” here can denote defined curing of the adhesive layer. In particular, the tackiness and/or the viscosity of the adhesive layer can be set by the initial curing before the chip is laid on. By way of example, the tackiness of the adhesive layer can be set by the initial curing in such a way that the tackiness is sufficient to fix a chip on the carrier. The viscosity of the adhesive layer can be set by the initial curing in such a way that the chip or the chips do not sink or sink only to a small extent into the adhesive layer.

By virtue of the defined initial curing of the adhesive layer, the viscosity and the tackiness of the adhesive layer can be set in such a way that, in the shaped body formed, the top side of the layer sequence and the first side of the shaped body lie substantially in a plane. “Lie substantially in a plane” in this context can mean that the planes defined by the respective sides have an offset of less than 2 μm.

The adhesive layer can be applied to the carrier by spin coating, spraying, lamination, jetting or thermoforming, for example. A polymer material with anti-adhesion properties can be provided as the material for the adhesive layer, for example. In particular, a silicone can be provided as the material for the adhesive layer. The silicone can be applied to the carrier in the non-crosslinked state.

The adhesive layer can be completely cured after the chip has been laid onto the adhesive layer and before the chip is embedded into the shaped body. After the complete curing, the material of the adhesive layer can be cross-linked. The adhesive layer may lose its tackiness as a result of the complete curing. The complete curing of the adhesive layer can prevent a situation, for example, in which the molding compound coalesces with the adhesive layer during the embedding of the chip. This can permit easier separation of the shaped body from the carrier after the chip has been embedded.

The adhesive film can therefore be cured in two separate steps, it being possible for less heat energy to be supplied in the first step, the initial curing, than in the second step, the complete curing. The parameters for the initial curing may depend on the material of the adhesive layer and/or on the properties of the adhesive layer which are to be set by the initial curing. By way of example, the initial curing of the adhesive layer can be effected at a temperature of less than or equal to 175° C. Furthermore, the initial curing of the adhesive layer can be effected for a period of time of less than or equal to 15 minutes. By way of example, given identical temperatures, at most half of the period of time which would be necessary for the complete curing of the adhesive layer can be provided for the initial curing. In particular, at most a quarter of the period of time provided for the complete curing of the adhesive layer can be provided for the initial curing.

A connection contact can be arranged on the substrate. The connection contact can be designed to electrically conductively contact-connect a layer of the layer sequence. An electrically conductive intermediate layer can be arranged on the connection contact. The intermediate layer can be designed to compensate for a difference in height between the top side of the layer sequence and the top side of the connection contact.

The connection contact can be exposed after the separation of the carrier and the shaped body. The connection contact can be exposed, for example, by means of laser drilling. The exposure of the connection contact may include removal of a region of the shaped body arranged above the connection contact.

A marginal region can be arranged between the layer sequence and a side edge of the first side of the substrate. The vertical electrical insulation can be arranged between the marginal region arranged on the substrate and the electrically conductive structure.

The shaped body can at least partially laterally surround the layer sequence. “At least partially” can mean that at least 50% of the lateral edge of the layer sequence is covered by molding compound. Furthermore, the shaped body can also completely laterally surround the layer sequence.

A plated-through hole can be arranged in the shaped body. The plated-through hole can be designed to connect electrically conductive structures on the first side of the shaped body to electrically conductive structures on the second side of the shaped body in an electrically conductive manner. The electrically conductive structure arranged on the first side of the shaped body can connect the layer sequence to the plated-through hole. The electrically conductive structure can contact-connect the layer sequence directly or indirectly. A “direct contact-connection” can mean that the electrically conductive structure lies on the layer of the layer sequence to be contact-connected. An “indirect contact-connection” can mean that the electrically conductive structure lies on a connection contact and the layer sequence is connected to the electrically conductive structure via the connection contact.

A recess filled with molding compound can be arranged between the layer sequence and the connection contact. The recess filled with molding compound can be filled with molding compound during the embedding of the chip, i.e. it can be part of the shaped body.

A reflector layer can be arranged between a lateral edge of the layer sequence and the shaped body. The reflector layer can surround the layer sequence. The reflector layer can be designed to reflect light emitted by the layer sequence in the direction of the shaped body.

A transparent insulation layer can be arranged between the lateral edge of the layer sequence and the reflector layer. The transparent insulation layer can be provided in particular when the reflector layer is electrically conductive.

### BRIEF DESCRIPTION OF THE FIGURES

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic illustration of a cross section of a first embodiment;

FIG. 2 shows a schematic illustration of a plan view onto the embodiment shown in FIG. 1;

FIGS. 3A-3F show schematic illustrations of a cross section of an embodiment for different method steps;

FIG. 4 shows a schematic illustration of a cross section of a second embodiment;

FIG. 5 shows a schematic illustration of a cross section of a third embodiment.

### DETAILED DESCRIPTION

The term “electronic component” may encompass, for example, optoelectronic components, logic components and power components. Hereinbelow, the proposed solution will be explained on the basis of an example of an optoelectronic component, the features explained for the optoelectronic component also being suitable for other component types.

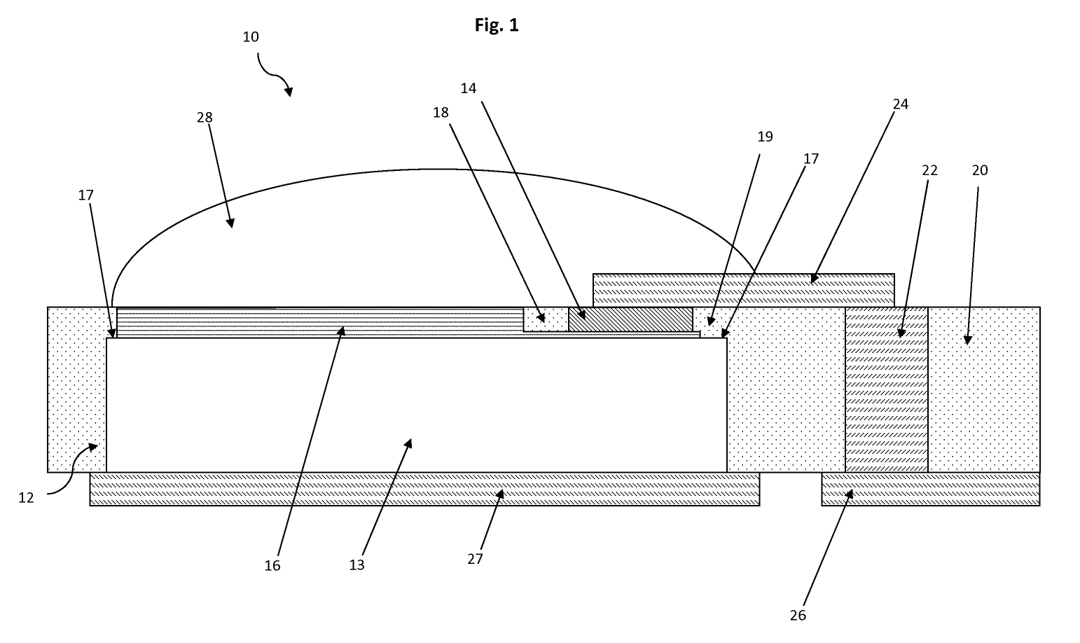

FIG. 1 shows a first embodiment of an electronic component 10. The component shown in FIG. 1 may be, for example, a light-emitting diode (LED). The component 10 includes a chip 12 and a shaped body 20. The chip 12 shown includes a substrate 13, a connection contact 14 and a layer sequence 16. The substrate 13 may be formed, for example, from a semiconductor material or another carrier material for optoelectronic components, such as for example sapphire.

The connection contact 14 and the layer sequence 16 are arranged on a first side of the substrate 13. The connection contact 14 may be an ohmic contact. In the case of the embodiment shown in FIG. 1, the connection contact 14 is a metallic layer. Aluminum or gold, for example, can be chosen as the material for the connection contact 14. The connection contact 14 is designed to electrically conductively contact-connect a layer of the layer sequence 16. By way of example, in the case of the embodiment shown in FIG. 1, the connection contact 14 is arranged directly on a layer of the layer sequence 16 which is to be electrically contact-connected. For the electrical contact-connection of layers of the layer sequence 16, provision can additionally be made of electrically conductive structures in the chip 12.

The layer sequence 16 may include a multiplicity of layers which have been applied, for example by epitaxial processes, to the first side of the substrate 13. A recess 18 may be provided between the layer sequence 16 and the connection contact 14. The recess 18 is filled with molding compound. In the case of the component shown in FIG. 1, the layer sequence 16 is designed to emit electromagnetic radiation. The electromagnetic radiation emitted by the layer sequence may also be referred to hereinbelow simply as light, the term “light” here also intending to denote electromagnetic radiation in the ultraviolet and infrared wavelength range which is invisible to humans.

The connection contact 14 and the layer sequence 16 do not extend as far as the edge of the substrate 13. Instead, a marginal region 17 is provided on the first side of the substrate 13 between the edge of the substrate 13 and the layer sequence 16, or the connection contact 14. The marginal region 17 may be a circumferential region arranged along the edges of the first side of the substrate 13. The marginal region 17 may be electrically insulating. The marginal region 17 may be provided, for example, in order to separate the layer sequence 16 and the connection contact 14 from the undefined—as a consequence of the singulation of the chip 12—electrical potential of the side faces of the chip 12.

The chip 12 is embedded in a shaped body 20 formed from molding compound. The shaped body 20 may be provided as a supportive structure for the chip 12. By way of example, the shaped body 20 may be provided as a mechanical carrier for the chip 12. In addition, the shaped body 20 can increase the surface area of the component 10 compared to the area of the chip 12. This may be desirable, for example, with respect to heat spreading and/or heat dissipation. The shaped body 20 may be provided for the mechanical, electrical and/or thermal connection of the chip 12 to an electronic subassembly. By way of example, the shaped body 20 can simplify the electrical contact-connection of the chip 12. Electrically conductive structures may be provided on and/or in the shaped body 20. Electrically conductive structures may include, for example, plated-through holes, layers of electrically conductive material and bonding connections. Furthermore, a plurality of chips 12 may also be embedded in a shaped body. Through the embedding of a plurality of chips into a shaped body, it is possible, for example, to provide large-area LED modules with a multiplicity of chips.

The top side of the shaped body 20, which is also referred to hereinbelow as the first side of the shaped body 12, lies substantially in a plane with the top side of the chip 12. In this case, the top side of the chip 12 is generally formed by the top side of the layer sequence 16. The wording “the sides lie substantially in a plane” can mean that the planes defined by the respective sides have an offset of less than or equal to 2 μm, it being possible in particular for the offset to be less than or equal to 1 μm. Furthermore, the first side of the shaped body 20 can terminate flush with the top side of the layer sequence 16. The shaped body 20 extends as far as the lateral edge of the connection contact 14 and/or of the layer sequence 16. The shaped body 20 therefore also covers the marginal region 17 of the substrate 13. The top side of the connection contact 14 and/or of the layer sequence 16 is not covered with molding compound. The top side is free from molding compound. Therefore, the top side of the connection contact 14 and/or of the layer sequence 16 is not embedded into the shaped body 20.

The bottom side of the shaped body 20, which is also referred to hereinbelow as the second side of the shaped body 20, lies in a plane with the bottom side of the chip 12, which is also referred to hereinbelow as the second side of the chip 12. The height of the shaped body 20 shown therefore corresponds substantially to the height of the chip 12. With the shape of the component 10 shown in FIG. 1, it is possible, for example, for very flat components to be realized. In other embodiments, it is also possible, for example, for the second side of the chip 12 to be embedded in molding compound.

By way of example, epoxy resin, silicone, epoxy/silicone hybrid material, glass or glass-ceramic can be provided as the material for the shaped body 20. Depending on the respective application, the shaped body 20 can be highly filled, for example, with quartz glass, titanium oxide, converter particles and/or scattering particles. Through the selection of suitable filling particles, a white, black, converting or transparent shaped body can be provided with respect to the respective application. The material of the shaped body 20 is electrically insulating. In other words, the shaped body 20 forms an electrical insulation.

In addition to the chip 12, a plated-through hole 22 is arranged in the shaped body 20. The plated-through hole 22 is electrically conductive. The plated-through hole 22 may be a cylinder formed from metal, for example. The plated-through hole 22 can be embedded into the shaped body 20 at the same time as the embedding of the chip 12. However, the plated-through hole 22 may also be introduced into the shaped body 20 independently of the embedding of the chip 12. The plated-through hole 22 may be provided, for example, in order to connect the connection contact arranged on the first side of the substrate 13 to contacts arranged on the bottom side of the shaped body 20. By way of example, soldered connections 26, 27 may be arranged on the second side of the shaped body 20. The soldered connections 26, 27 arranged on the second side of the shaped body 20 may be provided for the surface mounting of the component 10.

An electrically conductive structure 24 is arranged on the first side of the shaped body 20. In the case of the embodiment shown in FIG. 1, the electrically conductive structure 24 is formed as an electrically conductive layer. The electrically conductive layer 24 connects the connection contact 14 to the plated-through hole 22. Aluminum, copper, nickel, gold or silver can be chosen, for example, as the material for the electrically conductive layer 24. The electrically conductive layer 24 may be strip-shaped, for example. Part of the electrically conductive layer 24 lies directly on the first side of the shaped body 20. Since the shaped body 20 also covers the marginal region 17 of the substrate 13, that region of the shaped body 20 which covers the marginal region 17 forms an electrical insulation 19 between the electrically conductive layer 24 and the marginal region 17 of the substrate 13. Since, in the illustration of FIG. 1, this electrical insulation 19 is arranged beneath the electrically conductive layer 24 and above the marginal region 17, this portion of the shaped body can also be referred to as a vertical electrical insulation 19. By way of example, the vertical insulation 19 can have a height which corresponds approximately to the height of the layer sequence 16. In the case of the embodiment shown in FIG. 1, the connection contact 14 is connected to a first soldered connection 26 in an electrically conductive manner via the electrically conductive layer 24 and the plated-through hole 22. A second soldered connection 27 is arranged on the second side of the substrate 13. The first and/or the second soldered connection 27 can be designed for electrical contact-connection, for mechanical connection of the component 10 and/or for heat dissipation.

The second soldered connection 27 can therefore electrically conductively contact-connect a layer of the layer sequence 16 via electrically conductive regions in the substrate 13. Furthermore, the second soldered connection 27 can have a relatively large form, and therefore heat loss which arises during operation of the component 10 can be carried away via the substrate 13 and the second soldered connection 27.

The optoelectronic component 10 furthermore includes a coupling-out element 28. The coupling-out element 28 may be formed, for example, from a silicone or epoxy resin. The coupling-out element may have the form of a lens, for example. The coupling-out element 28 is transparent for the light emitted by the layer sequence 16.

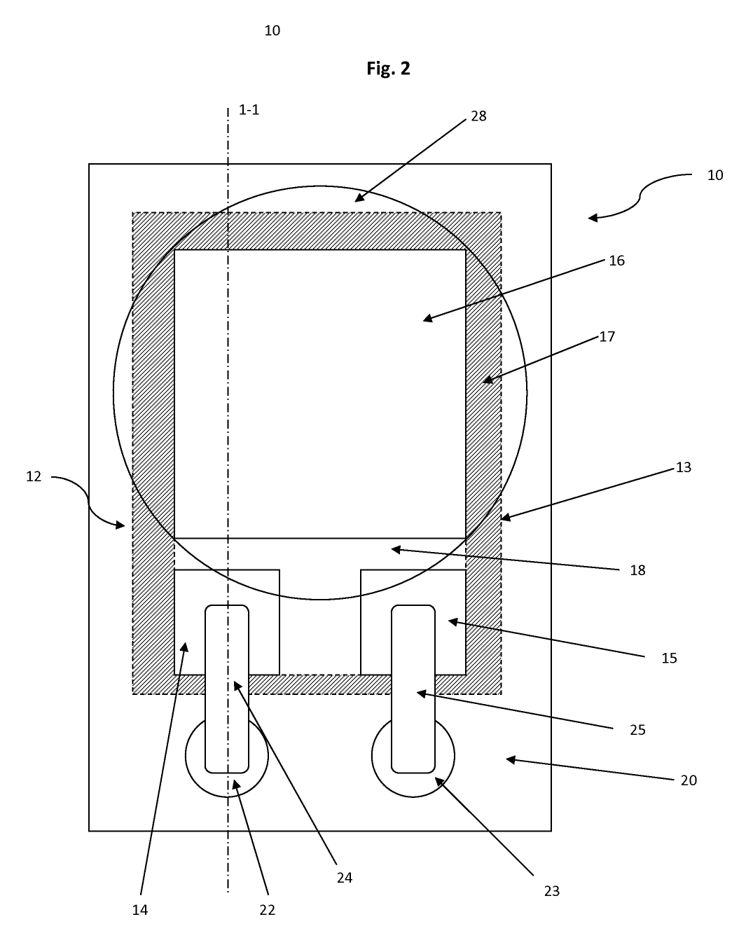

FIG. 2 is a schematic plan view onto the embodiment shown in FIG. 1, the line 1-1 shown in FIG. 2 denoting the position of the cross section shown in FIG. 1.

In the case of the embodiment shown in FIG. 2, the shaped body has a rectangular structure. The chip 12 is laterally surrounded by the shaped body 20. The top side of the layer sequence 16 and the connection contacts 14, 15 are not covered with molding compound. In the case of the illustration shown in FIG. 2, the substrate 13 is concealed by the shaped body 20. The dimensions of the substrate 13 are denoted by the dashed rectangle in FIG. 2. The marginal region 17 covered by the shaped body 20 is denoted by the shaded area in FIG. 2. FIG. 2 shows two electrically conductive structures and two plated-through holes. The first electrically conductive layer 24 connects the first connection contact 14 to the first plated-through hole 22. A second electrically conductive layer 25 connects a second connection contact 15 to a second plated-through hole 23. The recess 18 arranged laterally between the connection contacts 14, 15 and the layer sequence 16 is filled with potting compound. The coupling-out element 28 is denoted by the circle illustrated in FIG. 2.

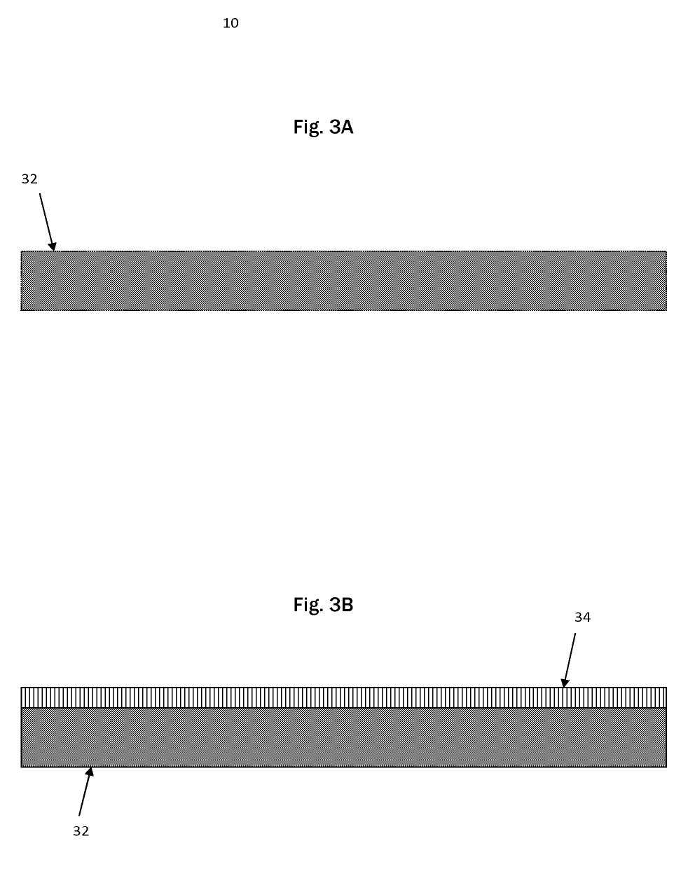

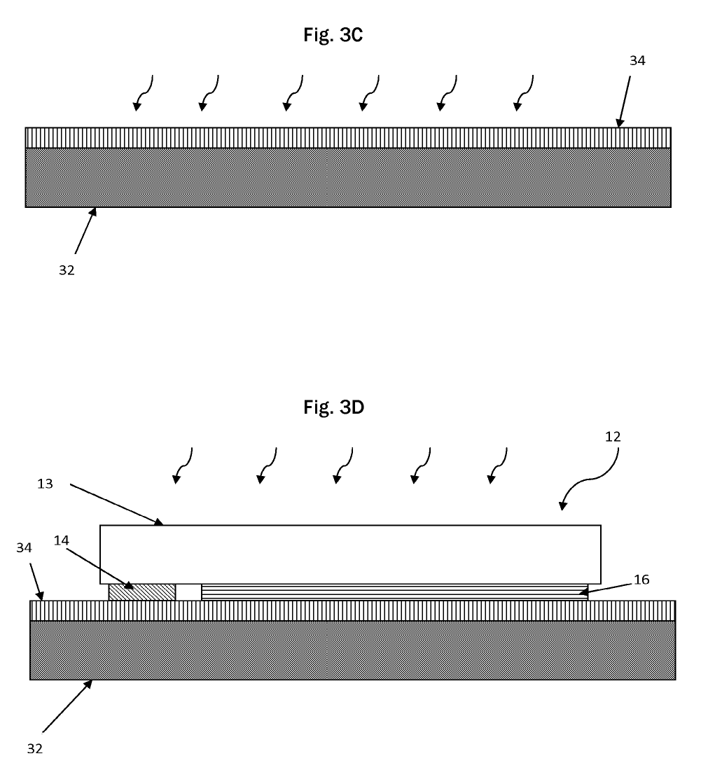

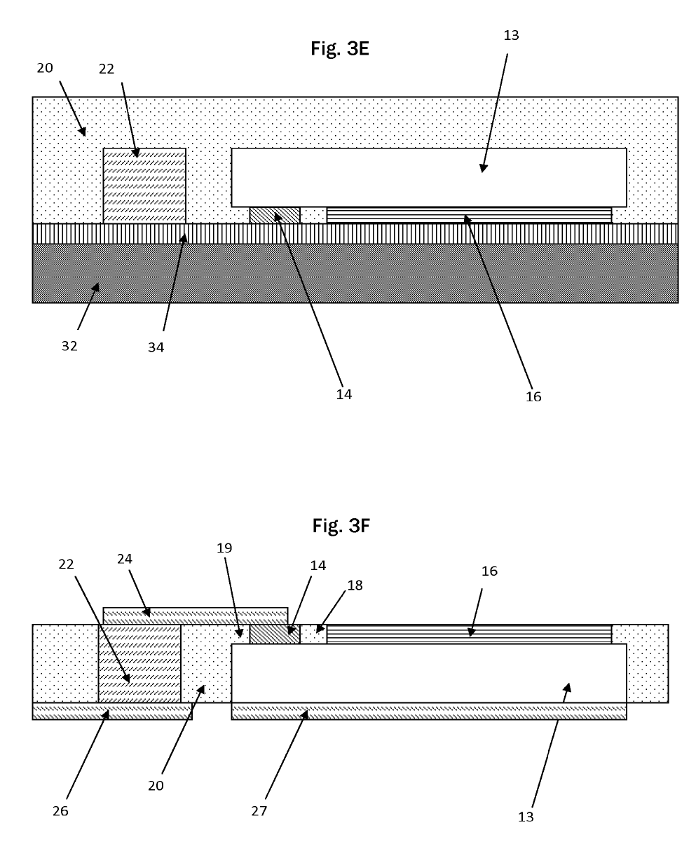

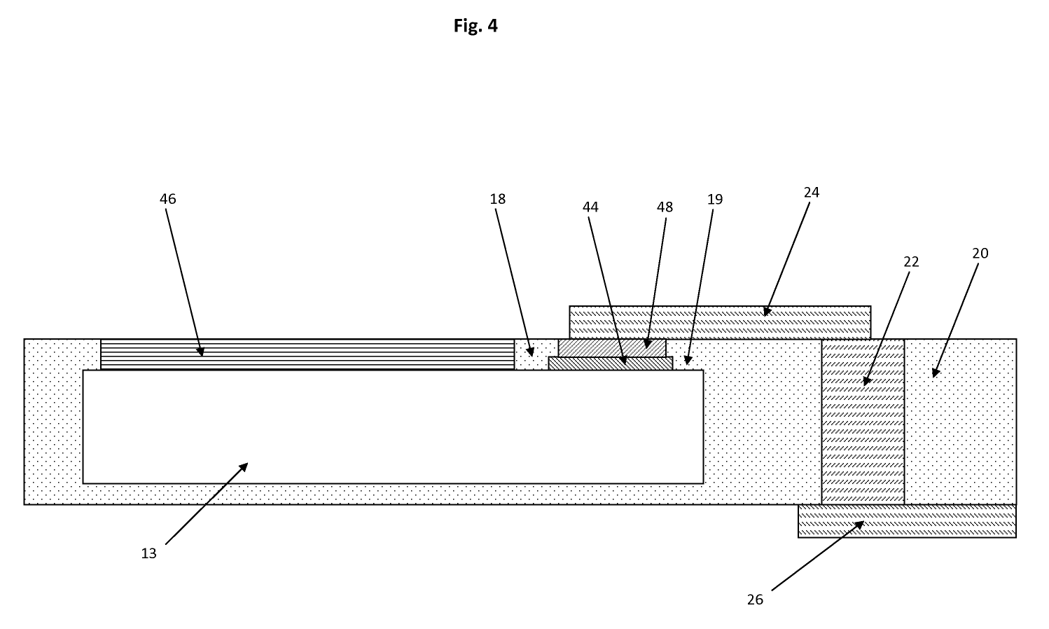

Hereinbelow, a method for producing an electronic component will be described in conjunction with FIGS. 3A-3F. FIGS. 3A-3F show a schematic illustration of a cross section of the first embodiment for different method steps. FIG. 3A shows a carrier 32. The carrier 32 serves as a support during the embedding of the chip 12. A semiconductor wafer, a ceramic plate, a glass plate or a metal plate can be provided, for example, as the carrier 32.

FIG. 3B shows an adhesive layer 34 applied to the carrier 32. The adhesive layer 34 can be applied to the carrier 32, for example, by spin coating, spraying, thermoforming or lamination. In the case of the embodiment shown, the adhesive layer 34 is applied by spin coating. By way of example, a rotational speed in a range from 2500 to 4000 revolutions/minute and a period of time in a range from 30 to 120 seconds can be provided as parameters for the application of the adhesive layer 34. The applied adhesive layer 34 may have a thickness of 1 μm to 50 μm.

In particular, the adhesive layer 34 may have a thickness of 10 μm to 20 μm.

Polymers with anti-adhesion properties, such as for example silicones, perfluoroalkoxy polymers (PFA) or polytetrafluoroethylene (PTFE), may be provided as the material for the adhesive layer 34. In particular, it is possible to select a material with anti-adhesion properties which has a certain tackiness during processing. The material can be applied to the carrier 32 in a non-crosslinked state. By way of example, the non-crosslinked state of the silicone can be referred to as the A stage.

The arrows illustrated in FIG. 3C denote initial curing of the adhesive layer 34. The initial curing can be effected, for example, by a controlled supply of heat energy. In one embodiment, the adhesive layer 34 can be initially cured, for example, at a temperature of 150° C. for 6 minutes. Depending on the material of the adhesive layer 34, energy in the form of electromagnetic radiation can also be supplied in addition and/or as an alternative. The adhesive layer 34 is partially cross-linked by the initial curing. The partially crosslinked state of silicone can be referred to as the B stage.

FIG. 3D shows a chip 12 laid with the layer sequence 16 onto the adhesive layer 34. On account of the properties of the adhesive layer 34 which have been set by the initial curing, the chip 12 does not sink or sinks only to a very small extent into the adhesive layer 34. The permissible sinking depth in this case depends on the respective application, but may be less than 2 μm for example. In particular, the permissible sinking depth may be less than or equal to 1 μm. By way of example, the viscosity of the adhesive layer 34 can be increased by the initial curing. Through the increased viscosity of the adhesive layer 34, the chip 12 does not sink or sinks only to a very small extent into the adhesive layer 34. The tackiness of the adhesive layer 34 can be reduced by the initial curing. The tackiness of the adhesive layer 34 is still high enough after the initial curing, however, for the chip 12 to be able to be fixed to the adhesive layer 34. In addition, the initial curing can prevent a situation in which the adhesive layer 34 wets the side face of the chip 12 and in particular the side faces of the layer sequence 16.

Once the chip 12 has been laid onto the adhesive layer 34, the adhesive layer 34 is completely cured. This is denoted by the arrows in FIG. 3D. To completely cure the adhesive layer 34, the carrier 32 together with the chip 12 can be stored, for example, at 150° C. for 60 minutes. It is therefore the case that significantly more heat energy is supplied during the complete curing than during the initial curing. In particular, the duration of the complete curing can exceed the duration of the initial curing. After the complete curing, the material of the adhesive layer 34 can be largely or completely crosslinked. In the case of silicone, the completely crosslinked state can be referred to as the C stage. The material of the adhesive layer 34 may lose its tackiness owing to the complete curing. The surface of the adhesive layer 34 can be smooth after the complete curing.

FIG. 3E shows the chip 12 embedded into the shaped body 20. A transfer molding process or a compression molding process can be provided, for example, for embedding the chip 12.

In addition to the chip 12, electrically conductive structures, such as for example the plated-through hole 22, can be embedded into the shaped body 20. The chip 12 and the electrically conductive structures can be embedded simultaneously.

Since the adhesive layer at best has a low residual tackiness after the complete curing, the molding compound does not coalesce with the adhesive layer during the embedding. Instead, the anti-adhesion properties of the material come to the fore after the complete curing. This facilitates the subsequent separation of the embedded chips 12 from the adhesive layer 34 and the carrier 32.

Depending on the application for which the component 10 is provided, the second side of the chip 12 may be covered with molding compound, as is shown for example in FIG. 3E, or may be free from molding compound, as is shown for example in FIG. 3F. If the second side of the chip 12 is not covered with molding compound, the second side of the shaped body 20 and the second side of the chip 12 can lie substantially in a plane. Proceeding from the state shown in FIG. 3E, it is possible, for example, for the second side of the shaped body 20 to be removed until the second side of the chip 12 is exposed. As an alternative thereto, the embedding of the chip 12 can even be configured in such a way that the second side of the chip 12 is not covered with molding compound during the embedding. This can be achieved, for example, by a suitable configuration of a transfer molding tool.

FIG. 3F shows the shaped body 20 with the embedded chip 12 after separation from the adhesive layer 34 and the carrier 32. After the separation, electrically conductive structures are attached on the first and/or second side of the shaped body 20. By way of example, electrically conductive structures in the form of electrically conductive layers 24, 25 can be attached to the first side of the shaped body 20. The electrically conductive layers 24, 25 respectively connect the connection contacts 14, 15 to the plated-through holes 22, 23. In addition, soldered connections respectively connected to the plated-through holes can be attached, for example, on the second side of the shaped body 20 and/or on the second side of the chip 12, these soldered connections being provided for the electrical contact-connection and also for the surface mounting of the component 10.

In the case of electronic components which are not designed to emit light, the soldered connections provided for the surface mounting can also be arranged, for example, on the first side of the shaped body 20. By way of example, the electrically conductive structure 24 attached on the first side of the shaped body 20 may be a soldered connection or may be electrically conductively connected to a soldered connection arranged on the first side of the shaped body 20. By way of example, the soldered connection can be a soldering bead, a solder globule and/or a connection area of a component with a BGA package form.

In addition, a coupling-out element 28 can be mounted above the shaped body. The coupling-out element 28 can be applied to the already embedded chip 12 in a separate molding process, for example.

FIG. 4 is a schematic cross-sectional illustration of a second embodiment. The second embodiment differs from the first embodiment, for example, in that the layer sequence 46 is higher than the connection contact 44. In other words, a first plane defined by the surface of the connection contact 44 is spaced apart from a second plane defined by the surface of the layer sequence 46. The spacing may be 6 μm, for example.

The spacing can be compensated for by an electrically conductive intermediate layer 48. The intermediate layer 48 may, for example, already be applied to the connection contact 44 during the front-end manufacturing, i.e. before the singulation of the chips 12. Aluminum can be selected, for example, as the material for the intermediate layer 48.

The intermediate layer 48 may also be applied to the connection contact 44 after the singulation of the chips 12 or else after the embedding of the chips 12. If the intermediate layer 48 is to be applied after the embedding of the chip 12, the surface of the connection contact 44 has to be exposed after the embedding. In particular, a region of the shaped body 20 which is formed above the connection contact 44 during the embedding has to be removed. By way of example, a hole extending as far as the connection contact 44 can be drilled into the shaped body 20 with a laser.

It is also possible, however, to dispense with the application of an intermediate layer. In this case, the connection contact 44 exposed after the embedding is contact-connected directly by an electrically conductive structure.

FIG. 4 additionally shows a shaped body 20, which also covers the second side of the chip 12. Whether the second side of the chip 12 is exposed, as is shown for example in FIG. 1, or is embedded into the shaped body 20, as is shown in FIG. 4, depends on the respective application of the component. Accordingly, this feature is independent of the form of the connection contact 44.

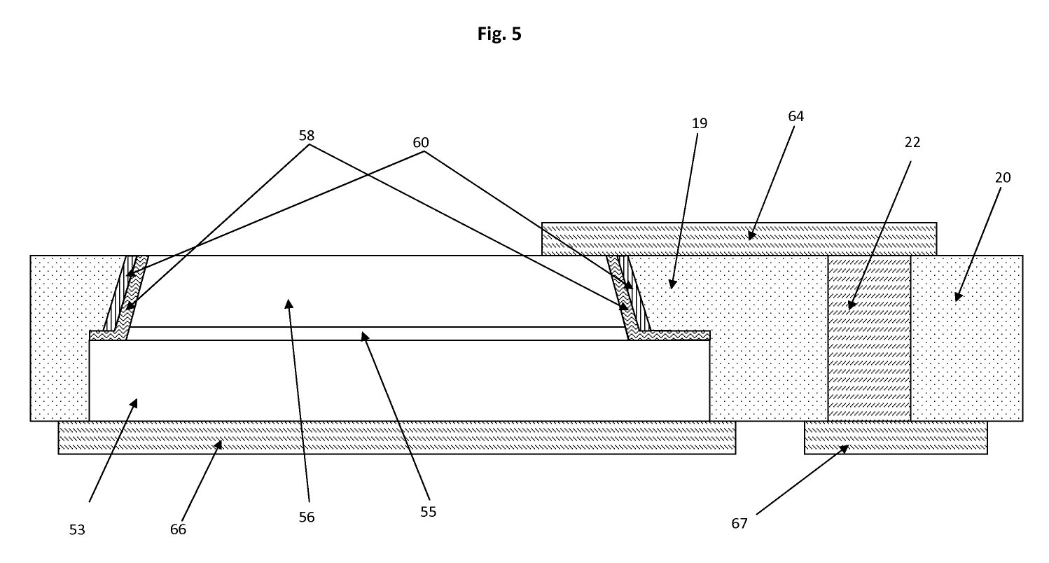

FIG. 5 schematically shows a cross section of a third embodiment. The chip 52 is embedded into a shaped body 20. At least one region of the substrate 53 of the chip 52 is electrically conductive. A layer sequence 56 is arranged on the substrate 53. The layer sequence 56 has a mirror layer 55. The mirror layer 55 can be arranged directly on the substrate 53 as the bottommost layer of the layer sequence 56. By way of example, silver can be selected as the material for the mirror layer 55. The mirror layer 55 is designed to reflect the light emitted by the layer sequence 56 in the direction of the substrate 53. Furthermore, the mirror layer 55 may be provided for the electrical contact-connection of the layer sequence 56. By way of example, the mirror layer 55 can be connected to an electrically conductive region of the substrate 53. This electrically conductive region of the substrate 53 can extend vertically through the substrate 53 and electrically conductively connect the mirror layer 55 to a first contact 66 attached to the second side of the substrate 53.

Furthermore, an electrically conductive structure 64 is arranged on the first side of the shaped body 20 for the electrical contact-connection of the layer sequence 56. The electrically conductive structure 64 lies on the layer sequence 56 and therefore contact-connects it directly. As an alternative or in addition to the direct contact-connection, an indirect contact-connection may also be provided. The electrically conductive structure 64 is electrically conductively connected via a plated-through hole 62 to a second contact 67 arranged on the second side of the shaped body 20. Between the first side of the substrate 53 and the electrically conductive structure 64, a region of the shaped body 20 forms a vertical insulation 19.

A transparent insulation layer 58 is arranged on the lateral edge of the layer sequence 56. The transparent insulation layer 58 is transparent for the light emitted by the layer sequence 56. In addition, the transparent insulation layer 58 forms an electrical insulation. By way of example, silicon oxide, aluminum oxide or silicon nitride can be selected as the material for the insulation layer 58.

A reflector layer 60 is arranged on the transparent insulation layer 58. By way of example, silver or aluminum can be selected as the material for the reflector layer 60. Furthermore, the reflector layer 60 can also be in the form of a Bragg mirror. If the reflector layer 60 is formed from an electrically insulating material, it is possible to dispense with the transparent insulation layer 56. The reflector layer 60 is designed to reflect the light emitted laterally by the layer sequence 56. As a result, the reflector layer 60 protects the shaped body 20 from the light emitted by the layer sequence 56. The ageing of the shaped body 20 which is caused by light can thus be slowed down.

The transparent insulation structure 58 and the reflector layer 60 may be part of the layer sequence 56. The transparent insulation structure 58 and the reflector layer 60 can be applied to the chip 12 during front-end manufacturing.

The mirror layer 55, the transparent insulation layer 58 and the reflector layer 60 are independent of the variant of the electrical contact-connection which is explained in conjunction with FIG. 5. Accordingly, these features can be provided individually or in combination also in the case of the embodiments explained in conjunction with FIGS. 1, 2, 3A-3F and 4.

The electronic component and the method for producing an electronic component have been described on the basis of a number of embodiments to illustrate the fundamental concept. These embodiments are not limited to specific combinations of features. Even if a number of features and configurations have been described only in connection with a particular embodiment or individual embodiments, they can each be combined with other features from other embodiments. It is likewise possible to omit or add individual presented features or particular configurations in embodiments, provided that the general technical teaching remains realized.

Even if the steps of the method for producing the electronic component are described in a specific order, nevertheless it goes without saying that each of the methods described in this disclosure can be carried out in any other expedient order, wherein method steps can also be omitted or added, provided that no departure is made from the basic concept of the technical teaching described.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A method for producing an electronic component, the method comprising:
applying an adhesive layer to a carrier;
initially curing the adhesive layer applied to the carrier;
providing a chip, the chip having a substrate and a layer sequence arranged on the substrate;
laying the chip onto the initially cured adhesive layer by way of a top side of the layer sequence;
embedding the chip into a shaped body, the top side of the layer sequence and a first side of the shaped body lying substantially in a plane;
separating the embedded chip from the adhesive layer and the carrier; and
applying an electrically conductive structure to the first side of the shaped body, the shaped body forming a vertical electrical insulation between the electrically conductive structure and the substrate.

2. The method as claimed in claim 1, wherein the adhesive layer is applied to the carrier by spin coating, spraying, lamination or thermoforming.

3. The method as claimed in claim 1, wherein the adhesive layer is completely cured after the chip has been laid onto the adhesive layer and before the chip is embedded into the shaped body.

4. The method as claimed in claim 1, wherein a polymer material with anti-adhesion properties is provided as the material for the adhesive layer.

5. The method as claimed in claim 1, wherein a connection contact arranged on the substrate is exposed after the separation of the carrier and the chip.

6. The method as claimed in claim 1, wherein the initial curing of the adhesive layer sets the viscosity and the tackiness of the adhesive layer in such a way that the top side of the layer sequence and the first side of the shaped body lie substantially in a plane.

7. The method as claimed in claim 1, wherein the adhesive layer is initially cured at a temperature of less than or equal to 175° C. and/or for a period of time of less than or equal to 15 minutes.

8. An electronic component having a chip embedded into a shaped body, wherein
the chip has a substrate and a layer sequence arranged on a first side of the substrate;
the shaped body has a first side which lies substantially in a plane with a top side of the layer sequence, and wherein the top side of the layer sequence is free from the shaped body;
an electrically conductive structure is arranged on the first side of the shaped body; and
a region of the shaped body forms a vertical electrical insulation between the electrically conductive structure and the first side of the substrate.

9. The electronic component as claimed in claim 8, wherein a marginal region is arranged between the layer sequence and a side edge of the first side of the substrate, and wherein the vertical electrical insulation is arranged between the marginal region and the electrically conductive structure arranged on the first side of the shaped body.

10. The electronic component as claimed in claim 8, wherein a connection contact is arranged on the first side of the substrate, and the connection contact is designed to electrically conductively contact-connect a layer of the layer sequence.

11. The electronic component as claimed in claim 10, wherein an electrically conductive intermediate layer is arranged on the connection contact, and the intermediate layer is designed to compensate for a difference in height between the top side of the layer sequence and a top side of the connection contact.

12. The electronic component as claimed in claim 10, wherein a recess filled with molding compound is arranged between the layer sequence and the connection contact, and wherein the recess filled with molding compound forms a region of the shaped body.

13. The electronic component as claimed in claim 8, wherein a plated-through hole is arranged in the shaped body, and the electrically conductive structure arranged on the first side of the shaped body connects the layer sequence and the plated-through hole in an electrically conductive manner.

14. The electronic component as claimed in claim 8, wherein a reflector layer is arranged on a lateral edge of the layer sequence.

15. The electronic component as claimed in claim 14, wherein the reflector layer is arranged on a transparent insulation layer.
